(19) United States
(12) Patent Application Publication
(10) Pub. No.: US 2022/0237451 A1
(43) Pub. Date: Jul. 28, 2022

(54) SEMICONDUCTOR PROCESS PREDICTION METHOD AND SEMICONDUCTOR PROCESS PREDICTION APPARATUS FOR HETEROGENEOUS DATA

(71) Applicant: UNITED MICROELECTRONICS CORP., Hsinchu (TW)

(72) Inventor: Hsin-Ming HOU, Tainan City (TW)

(21) Appl. No.: 17/213,817

(22) Filed: Mar. 26, 2021

(30) Foreign Application Priority Data
Jan. 28, 2021 (CN) 202110118097.6

(51) Int. Cl. G06N 3/08; G06N 3/04; G06F 16/23

(52) U.S. Cl. CPC G06N 3/08; G06F 16/2379; G06N 3/0454

(57) ABSTRACT

A method and an apparatus for semiconductor manufacturing process prediction based on heterogeneous data are provided. The method includes the following steps. Several equipment recipe data of several pieces of equipment are obtained. The equipment recipe data are inputted into a first Neural Network model to obtain a first prediction result. Several equipment sensing data are obtained. The equipment sensing data are inputted into a second Neural Network model to obtain a second prediction result. Several metrology inspection data are obtained. The equipment recipe data, the equipment sensing data and the metrology inspection data are heterogeneous data. The metrology inspection data are inputted into a third Neural Network model to obtain a third prediction result. According to the first prediction result, the second prediction result and the third prediction result, a total prediction result is obtained.

This application claims the benefit of People's Republic of China application Serial No. 202110118097.6, filed Jan. 28, 2021, the disclosure of which is incorporated by reference herein in its entirety.

### TECHNICAL FIELD

The disclosure relates in general to a semiconductor process prediction method and a semiconductor process prediction apparatus, and more particularly to a semiconductor process prediction method and a semiconductor process prediction apparatus for heterogeneous data.

### BACKGROUND

With the development of semiconductor technology, various types of complex semiconductor products are constantly being introduced. In the semiconductor process, the wafer needs to go through tens of thousands of processes to produce the final product. Therefore, researchers use appropriate prediction methods in the semiconductor process to predict the electrical function and yield of the final product, so as to avoid a large number of defective products in the final products.

The TOAD simulation system is traditionally used to estimate the electrical function of the final product. However, this method is used in a single line process, under very strict boundary conditions through electromagnetic theory for prediction. With the trend of increasing complexity of the semiconductor process, it has been difficult to produce prediction results with higher accuracy.

### SUMMARY

The disclosure is directed to a semiconductor process prediction method and a semiconductor process prediction apparatus for heterogeneous data. The equipment recipe data, the equipment sensing data, and the metrology inspection data which are heterogeneous data are obtained from the pipe line to obtain highly accurate prediction results.

According to one embodiment, a semiconductor process prediction method for heterogeneous data is provided. A plurality of equipment recipe data of a plurality of pieces of equipment are obtained. The equipment recipe data are inputted into a first Neural Network model, to obtain a first prediction result. A plurality of equipment sensing data are obtained. The equipment sensing data are inputted into a second Neural Network model to obtain a second prediction result. A plurality of metrology inspection data are obtained. The equipment recipe data, the equipment sensing data and the metrology inspection data are heterogeneous data. The metrology inspection data are inputted into a third Neural Network model, to obtain a third prediction result. A total prediction result is obtained according to the first prediction result, the second prediction result and the third prediction result.

According to another embodiment, a semiconductor process prediction apparatus for heterogeneous data is provided. The semiconductor process prediction apparatus includes a first database, a first Neural Network model, a second database, a second Neural Network model, a third database, a third Neural Network model and a total prediction unit. The first database is configured to storing a plurality of equipment recipe data of a plurality of pieces of equipment. The first Neural Network model is configured to receive the equipment recipe data to obtain a first prediction result. The second database is configured to storing a plurality of equipment sensing data. The second Neural Network model is configured to receive the equipment sensing data to obtain a second prediction result. The third database is configured to storing a plurality of metrology inspection data. The equipment recipe data, the equipment sensing data and the metrology inspection data are heterogeneous data. The third Neural Network model is configured to receive the metrology inspection data to obtain a third prediction result. The total prediction unit is configured to obtain a total prediction result according to the first prediction result, the second prediction result and the third prediction result.

### BRIEF DESCRIPTION OF THE DRAWINGS

FIG. 1 shows a schematic diagram of a semiconductor process using a pipe line production according to an embodiment.

FIG. 2 shows a block diagram of a semiconductor process prediction apparatus according to an embodiment.

FIG. 3 shows a flowchart of a semiconductor process prediction method for the heterogeneous data according to an embodiment.

FIG. 4 illustrates the steps in FIG. 3.

FIG. 5 shows a flowchart of the detailed steps of step S140.

FIG. 6 illustrates the steps of FIG. 5.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

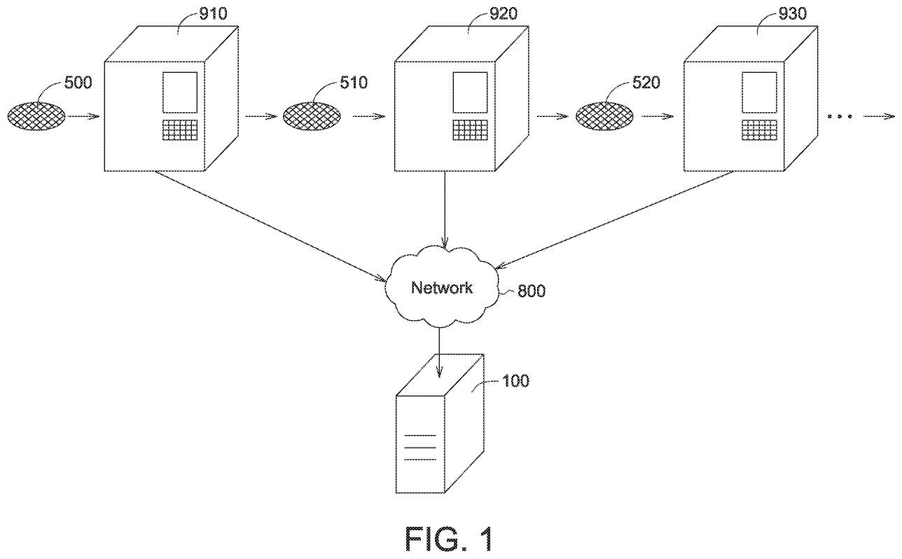

Please refer to FIG. 1, which shows a schematic diagram of a semiconductor process using a pipe line production according to an embodiment. In the semiconductor process using the pipeline production, several processes executed by several pieces of equipment 910, 920, 930, etc., are executed successively. When a wafer 500 enters the equipment 910 for semiconductor process, a wafer 510 also enters the equipment 920 for semiconductor process. The pieces of equipment 910, 920, 930, etc., are operated continuously without stopping to maximize the efficiency of the pieces of equipment 910, 920, 930, etc. Various information in the process can be transmitted to the semiconductor process prediction apparatus 100 through the network 800 to predict the electrical function and yield of the final product.

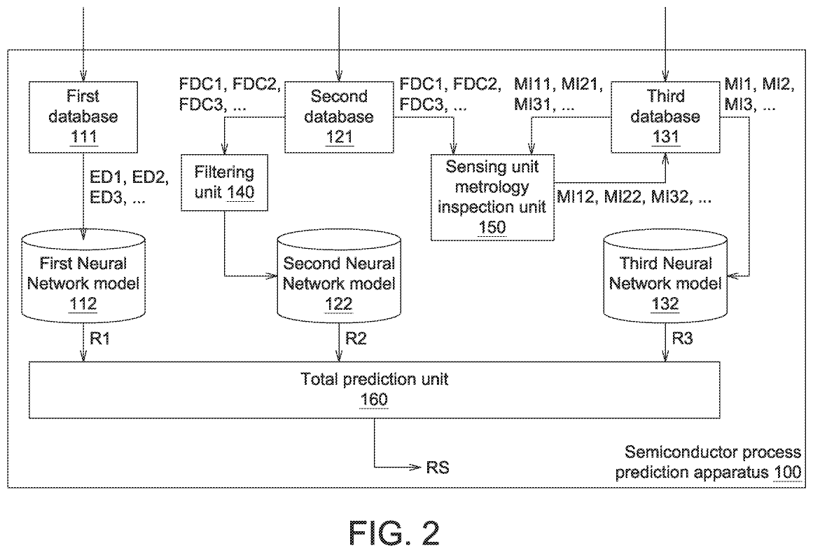

Please refer to FIG. 2, which shows a block diagram of a semiconductor process prediction apparatus 100 according to an embodiment. The semiconductor process prediction apparatus 100 includes a first database 111, a first Neural Network model 112, a second database 121, a second Neural Network model 122, a third database 131, a third Neural Network model 132, a filtering unit 140, a metrology inspection unit 150 and a total prediction unit 160. The functions of the components are summarized as follows. The first database 111, the second database 121 and the third database 131 are used to store various data. The first database 111, the second database 121 and the third database 131 are, for example, a memory, a hard disk or a cloud storage center. The first Neural Network model 112, the second Neural Network model 122 and/or the third Neural Network model 132 are used for data prediction. The filtering unit 140 is used for data filtering. The first Neural Network model 112, the second Neural Network model 122, the third Neural Network model 132, the filtering unit 140, the metrology inspection unit 150 and/or the total prediction unit 160 are, for example, program code, a circuit, a chip, and a circuit board or a storage device that stores the program code. Through the above components, the semiconductor process prediction apparatus 100 can use various heterogeneous data obtained from the pipeline production to obtain highly accurate prediction results.

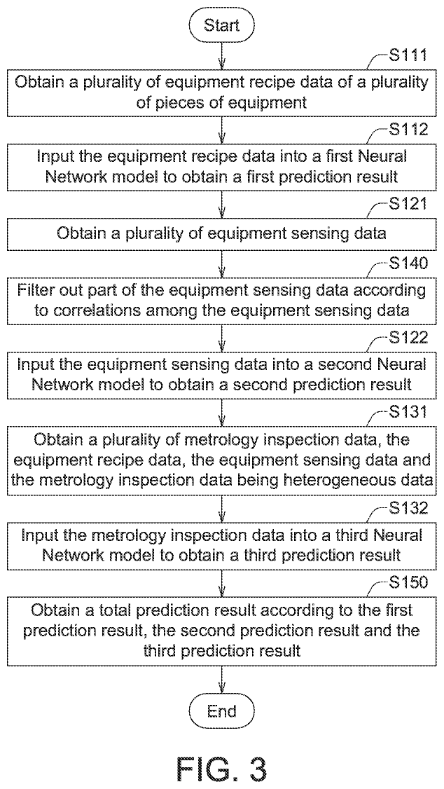

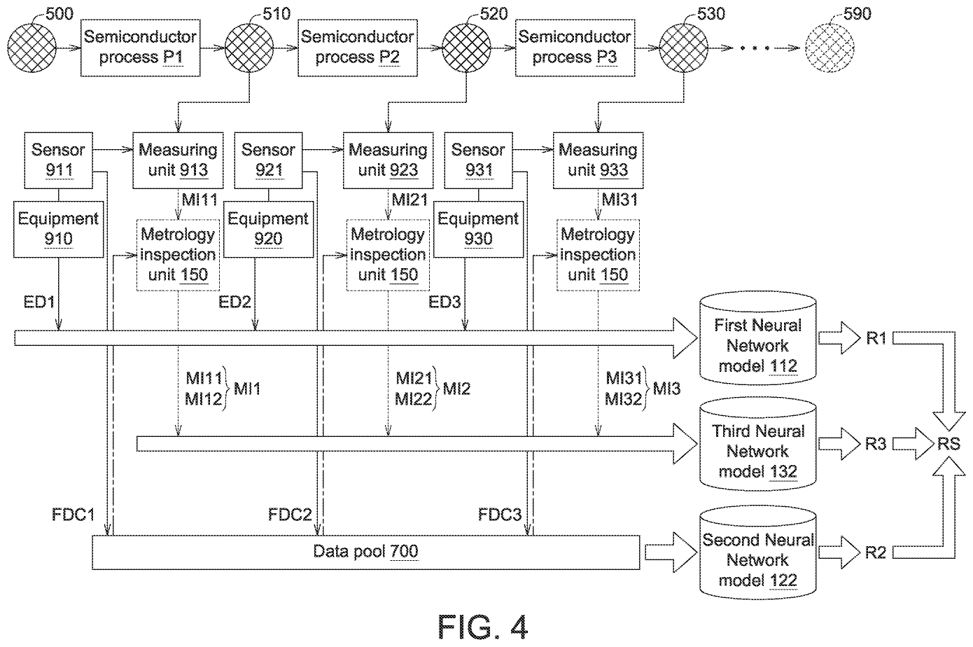

Please refer to FIGS. 3 and 4. FIG. 3 shows a flowchart of a semiconductor process prediction method for the heterogeneous data according to an embodiment. FIG. 4 illustrates the steps in FIG. 3. As shown in FIG. 4, the wafer 500 needs to go through the semiconductor processes P1, P2, P3, and so on, to obtain the final product 590. When the wafer 500 is performed the semiconductor process P1, the wafer 510 is performed the semiconductor process P2, the wafer 520 is performed semiconductor process P3, and so on.

Each piece of equipment 910, 920, 930, etc., has set equipment recipe data ED1, ED2, ED3, etc. The equipment recipe data ED1, ED2, ED3, etc., are, for example, pressure setting value, valve opening time, heating time, etc. The equipment recipe data ED1, ED2, ED3, etc., are discrete numerical data. The setting items of the pieces of equipment 910, 920, 930, etc., are different, and the contents of equipment recipe data ED1, ED2, ED3, etc., are also different.

Each piece of equipment 910, 920, 930, etc., will also obtain equipment sensing data FDC1, FDC2, FDC3, etc., through sensors 911, 921, 931, etc. The equipment sensing data FDC1, FDC2, FDC3, etc., are for example, pressure, gas concentration, temperature, etc. The equipment sensing data FDC1, FDC2, FDC3, etc., are continuous numerical data. The equipment sensing data FDC1, FDC2, FDC3, etc., are continuously collected in data pool 700.

When the semiconductor processes P1, P2, P3, etc., respectively output the wafers 510, 520, 530 etc., the physical measurement will also be performed to obtain metrology inspection data MI1, MI2, MI3, etc. The metrology inspection data MI1, MI2, MI3, etc., are, for example, as thickness, wire width, perforation distance, etc. The metrology inspection data MI1, MI2, MI3, etc., are discrete numerical data.

The above-mentioned equipment recipe data ED1, ED2, ED3, etc., the equipment sensing data FDC1, FDC2, FDC3, etc., and the metrology inspection data MI1, MI2, MI3, etc., are heterogeneous data. These data have their own advantages in process prediction, and this disclosure combines the advantages of these heterogeneous data to improve prediction accuracy.

First, in step S111, the equipment recipe data ED1, ED2, ED3, etc., of the pieces of equipment 910, 920, 930, etc., are obtained from the first database 111.

Next, in step S112, the equipment recipe data ED1, ED2, ED3, etc., are inputted into the first Neural Network model 112 to obtain a first prediction result R1. The first Neural Network model 112 is, for example, Supervised Learning Network, Unsupervised Learning Network, Hybrid Learning Network, Associate Learning Network, Optimization Application Network, etc. The first Neural Network model 112 receives the equipment recipe data ED1, ED2, ED3, etc., from the combination of the equipment recipe data ED1, ED2, ED3, etc., the electrical function and yield of the final product 590 can be predicted.

Then, in step S121, the equipment sensing data FDC1, FDC2, FDC3, etc., of the pieces of equipment 910, 920, 930, etc., are obtained from the second database 121.

Next, in step S140, the filtering unit 140 filters out part of the equipment sensing data FDC1, FDC2, FDC3, etc., according to the correlations among the equipment sensing data FDC1, FDC2, FDC3, etc. Since the equipment sensing data FDC1, FDC2, FDC3, etc., have a huge amount of data and has co-linearity, this step can be used to filter out representative content to eliminate the effect of co-linearity.

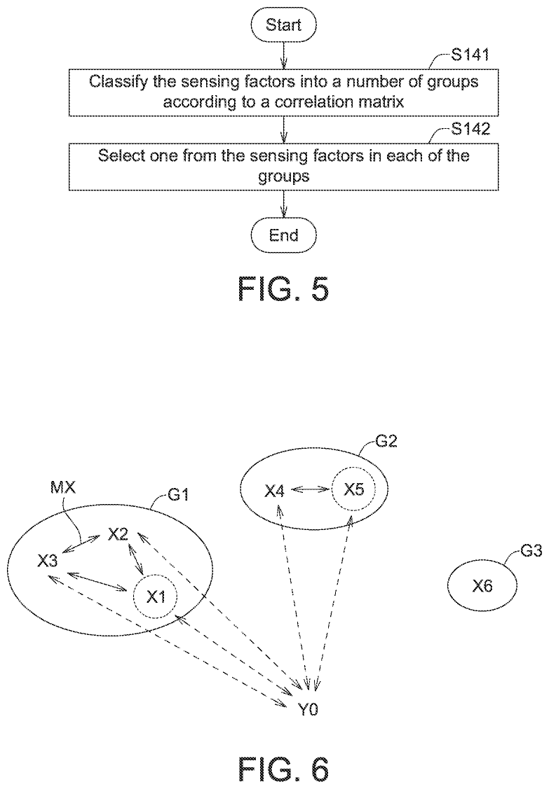

Please refer to FIGS. 5 and 6. FIG. 5 shows a flowchart of the detailed steps of step S140. FIG. 6 illustrates the steps of FIG. 5. The step S140 includes steps S141 and S142. In the example shown in FIG. 6, the equipment sensing data FDC1 has 6 sensing factors X1 to X6, which are temperature, pressure, gas concentration, etc. In step S141, the filtering unit 140 classifies the sensing factors X1 to X6 into a number of groups G1 to G3 according to a correlation matrix MX. The correlation matrix MX records the correlation coefficients (as shown by the solid double arrow in FIG. 6) between any two of the sensing factors X1 to X6. Those whose relationship coefficient is greater than a predetermined threshold are classified into the same group. As shown in FIG. 6, the sensing factors X1 to X3 are classified as the group G1; the sensing factors X4 to X5 are classified as the group G2; the sensing factor X6 is classified as the group G3.

Next, in step S142, the filtering unit 140 selects one from the sensing factors in each of the groups G1, G2, G3. That is, the sensing factors X1, X5, X6 are selected from the groups G1, G2, G3 respectively. Only one sensing factor is selected from each of the groups G1, G2, G3. In the group G1, the sensing factor X1 having the largest correlation coefficient (as shown by the dashed double arrow in FIG. 6) to prediction target Y0 is selected. In the group G2, the sensing factor X5 having the largest correlation coefficient (as shown by the dashed double arrow in FIG. 6) to prediction target Y0 is selected. As a result, the selected sensing factors X1, X5, and X6 have a low correlation and no co-linearity. In addition, the selected sensing factors X1, X5, X6 have higher correlation coefficients relative to the prediction target Y0, and are the most representative.

Each of the equipment sensing data FDC1, FDC2, FDC3, etc., can be reduced to representative content by performing the above-mentioned filtering step.

Afterwards, in the step S122 of FIG. 3, the equipment sensing data FDC1, FDC2, FDC3, etc., are inputted into the second Neural Network model 122 to obtain a second prediction result R2. The second Neural Network model 122 is, for example, Supervised Learning Network, Unsupervised Learning Network, Hybrid Learning Network, Associate Learning Network, Optimization Application Network, etc.

Next, in step S131, the metrology inspection data MI1, MI3, MI4, etc., are obtained from the third database 131. As shown in FIG. 4, the metrology inspection data MI1 includes a plurality of actual measurement data MI11 and a plurality of virtual measurement data MI12. The large number of the wafers 510 makes it difficult to perform the physical measurements one by one. Therefore, the measuring unit 913 can perform the physical measurements on a small part of the wafers 510, and obtain actual measurement data MI11. The metrology inspection unit 150 can perform a simulation procedure based on the actual measurement data MI11 and the equipment sensing data FDC1 (and/or the equipment recipe data ED1) to obtain the virtual measurement data MI12. Similarly, the measuring unit 923, 933 can perform the physical measurements on a small part of the wafers 520, 530, and obtain actual measurement data MI21, MI31. The metrology inspection unit 150 can perform simulation procedures based on the actual measurement data MI21, MI31 and the equipment sensing data FDC2, FDC3 (and/or the equipment recipe data ED2, ED3) to obtain virtual measurement data MI22, MI32, and so on.

Afterwards, in step S132, the metrology inspection data MI1, MI2, MI3, etc., are inputted into the third Neural Network model 132 to obtain a third prediction result R3. The third Neural Network model 132 is, for example, Supervised Learning Network, Unsupervised Learning Network, Hybrid Learning Network, Associate Learning Network, Optimization Application Network, etc.

Next, in step S150, the total prediction unit 160 obtains a total prediction result RS according to the first prediction result R1, the second prediction result R2, and the third prediction result R3. In this step, the total prediction unit 160 can obtain the total prediction result RS through a voting procedure.

According to the above embodiments, the semiconductor process prediction apparatus 100 and the semiconductor process prediction method can utilize the equipment recipe data ED1, ED2, ED3, etc., the equipment sensing data FDC1, FDC2, FDC3, etc., the metrology inspection data MI1, MI2, MI3, etc. obtained from pipeline production, which are heterogeneous data to obtain highly accurate prediction results.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor process prediction method for heterogeneous data, comprising:
obtaining a plurality of equipment recipe data of a plurality of pieces of equipment;
inputting the equipment recipe data into a first Neural Network model, to obtain a first prediction result;
obtain a plurality of equipment sensing data;
inputting the equipment sensing data into a second Neural Network model, to obtain a second prediction result;
obtaining a plurality of metrology inspection data, wherein the equipment recipe data, the equipment sensing data and the metrology inspection data are heterogeneous data;
inputting the metrology inspection data into a third Neural Network model, to obtain a third prediction result; and
obtaining a total prediction result according to the first prediction result, the second prediction result and the third prediction result.

2. The semiconductor process prediction method for heterogeneous data according to claim 1, further comprising:
filtering out part of the equipment sensing data according to correlations among the equipment sensing data.

3. The semiconductor process prediction method for heterogeneous data according to claim 1, wherein each of the equipment recipe data is discrete numerical data.

4. The semiconductor process prediction method for heterogeneous data according to claim 1, wherein each of the equipment sensing data is continuous numerical data.

5. The semiconductor process prediction method for heterogeneous data according to claim 1, wherein each of the metrology inspection data is discrete numerical data.

6. The semiconductor process prediction method for heterogeneous data according to claim 1, wherein a plurality of processes executed by the pieces of equipment are continuously executed.

7. The semiconductor process prediction method for heterogeneous data according to claim 1, wherein the metrology inspection data includes a plurality of actual measurement data and a plurality of virtual measurement data, and the virtual measurement data is obtained by performing a simulation procedure according to the actual measurement data and the equipment sensing data.

8. The semiconductor process prediction method for heterogeneous data according to claim 1, wherein in the step of obtaining the total prediction result according to the first prediction result, the second prediction result and the third prediction result, the total prediction result is obtained through a voting procedure.

9. A semiconductor process prediction apparatus for heterogeneous data, comprising:
a first database, configured to storing a plurality of equipment recipe data of a plurality of pieces of equipment;
a first Neural Network model, configured to receive the equipment recipe data to obtain a first prediction result;
a second database, configured to storing a plurality of equipment sensing data;
a second Neural Network model, configured to receive the equipment sensing data to obtain a second prediction result;
a third database, configured to storing metrology inspection data, wherein the equipment recipe data, the equipment sensing data and the metrology inspection data are heterogeneous data;
a third Neural Network model, configured to receive the metrology inspection data to obtain a third prediction result; and
a total prediction unit, configured to obtain a plurality of total prediction result according to the first prediction result, the second prediction result and the third prediction result.

10. The semiconductor process prediction apparatus for heterogeneous data according to claim 9, further comprising:
a filtering unit, configured to filter out part of the equipment sensing data according to correlations among the equipment sensing data.

11. The semiconductor process prediction apparatus for heterogeneous data according to claim 9, wherein each of the equipment recipe data is discrete numerical data.

12. The semiconductor process prediction apparatus for heterogeneous data according to claim 9, wherein each of the equipment sensing data is continuous numerical data.

13. The semiconductor process prediction apparatus for heterogeneous data according to claim 9, wherein each of the metrology inspection data is discrete numerical data.

14. The semiconductor process prediction apparatus for heterogeneous data according to claim 9, wherein a plurality of processes executed by the pieces of equipment are continuously executed.

15. The semiconductor process prediction apparatus for heterogeneous data according to claim 9, wherein the metrology inspection data includes a plurality of actual measurement data and a plurality of virtual measurement data, and the virtual measurement data is obtained by performing a simulation procedure according to the actual measurement data and the equipment sensing data.

16. The semiconductor process prediction apparatus for heterogeneous data according to claim 9, wherein the total prediction unit obtains the total prediction result through a voting procedure.
